(19) United States
(12) Patent Application Publication
(10) Pub. No.: US 2025/0266265 A1
(43) Pub. Date: Aug. 21, 2025

(54) METHODS AND SYSTEMS FOR ETCHING

(71) Applicant: ASM IP Holding B.V., Almere (NL)

(72) Inventors: Mikko Ritala, Espoo (FI); Marko Vehkamäki, Helsinki (FI); Juha Ojala, Helsinki (FI)

(21) Appl. No.: 19/051,235

(22) Filed: Feb. 12, 2025

Related U.S. Application Data
(60) Provisional application No. 63/553,680, filed on Feb. 15, 2024.

(51) Int. Cl. H01L 21/3213; H01L 21/67

(52) U.S. Cl. CPC H01L 21/32135; H01L 21/67069

(57) ABSTRACT

Methods and related systems for etching are disclosed for etching an etchable layer by executing a cyclical etching process comprising a plurality of etching cycles. Ones from the plurality of etching cycles comprise a volatilization reactant pulse that comprises exposing a substrate to a volatilization reactant.

### CROSS-REFERENCE TO RELATED APPLICATIONS

This application claims priority to and benefit of U.S. Provisional Application No. 63/553,680, filed Feb. 15, 2024, the entirety of which is incorporated by reference herein.

### FIELD OF INVENTION

The present disclosure relates to the field of integrated circuit processing, and particularly to etching processes and systems for integrated circuit manufacture.

### BACKGROUND OF THE DISCLOSURE

The patterning of metal interconnects and diffusion barriers is a crucial part of their manufacturing process. Current industry standard is the damascene process, where gaps for Cu interconnects are overfilled and extraneous material is removed with chemical and/or mechanical polishing. This process is limited to planar processing. Patterning by direct material removal of metals most often uses wet etching methods and plasma-based reactive ion etching (RIE). The use of plasma can cause damage to unetched layer(s) and surrounding materials through embedding of energetic ions to the material. RIE is also characterized as an anisotropic etching method, which limits its use for etching non-line-of-sight features.

Thermal atomic layer etching is an isotropic gas phase etching method, which avoids plasma damage by using thermally activated chemical reactions for the etching. It is based on self-limiting chemical modification of the surface to be etched followed by volatilization of the modified surface layer. This enables conformal and highly controlled etching of materials.

Ta and TaN have been used as diffusion barriers for Cu interconnects. Mo is one of the metals proposed as a replacement for Cu due to its potential for barrierless integration and the smaller mean free path of electrons, which means that its resistivity scales more slowly at very low conductor dimensions.

Miniaturization of integrated circuits is reaching the point where scaling of Cu interconnects is becoming increasingly difficult due to the physical properties of the metal and requirement for diffusion barriers between the interconnect and dielectric layers. New materials for thinner diffusion barriers and for replacing Cu to enable barrierless integration are being investigated. At the same time, 3D integration is increasing the requirements of materials processing technology.

Thermally activated gas phase etching methods allow for isotropic etching of materials with minimal damage to the underlying materials. Most of the existing thermal etching methods rely on fluoride-based etchants, which can be very aggressive towards different materials. This poses a challenge for selectivity and requires extra protection for the process equipment.

### SUMMARY OF THE DISCLOSURE

Disclosed herein is an embodiment of a method of etching, comprising providing a substrate to a reaction chamber, the substrate comprising an etchable layer, the etchable layer comprising a metal; executing a cyclical etching process comprising a plurality of etching cycles, at least one of the plurality of etching cycles comprising a conversion reactant pulse that comprises exposing the substrate to a conversion reactant; at least one from the plurality of etching cycles comprising a volatilization reactant pulse that comprises exposing the substrate to a volatilization reactant; thereby etching the etchable layer; wherein the volatilization reactant comprises a metal halide.

In some embodiments, at least one of plurality of etching cycles comprises both a conversion reactant pulse that comprises exposing the substrate to a conversion reactant and a volatilization reactant pulse that comprises exposing the substrate to a volatilization reactant.

In some embodiments, the substrate further comprises a second layer, and wherein the second layer is not substantially etched during the cyclical etching process, thus selectively etching the etchable layer versus the second layer.

In some embodiments, the cyclical etching process is carried out thermally.

In some embodiments, the conversion reactant comprises an oxygen reactant.

In some embodiments, the oxygen reactant comprises O₂.

Further described herein is an embodiment of a method of selectively etching, comprising providing a substrate to a reaction chamber, the substrate comprising an etchable layer, the etchable layer comprising a metal, the substrate further comprising a second layer; executing a cyclical etching process that comprises alternatingly exposing the substrate to a vaporization reactant and a purge gas; thereby etching the etchable layer; wherein the volatilization reactant comprises a metal halide; and, wherein the second layer is not substantially etched during the cyclical etching process.

In some embodiments, the volatilization reactant comprises a transition metal halide. In some embodiments, the volatilization reactant comprises a transition metal chloride. In some embodiments, the volatilization reactant comprises niobium pentachloride (NbCl₅). In some embodiments, the etchable layer comprises at least 90 atomic percent of the metal. In some embodiments, the metal comprises a transition metal. In some embodiments, the transition metal comprises at least one of tantalum and molybdenum.

In some embodiments, the etchable layer comprises at least one of Ta₂O₅, TiO₂ or ZrO₂.

In some embodiments, the second layer comprises at least one of HfO₂, SiO₂, Al₂O₃, or TiN.

In some embodiments, the cyclical etching process is carried out at a temperature of at least 250° C. to at most 450° C.

In some embodiments, the volatilization reactant pulse is followed by a first purge.

In some embodiments, the conversion reactant pulse is followed by a second purge.

Further described herein is a system comprising a reaction chamber, a substrate support, and a controller, the controller being configured for causing the system to execute a method as described herein.

In some embodiments, the system does not comprise a plasma source.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter

### BRIEF DESCRIPTION OF THE DRAWING FIGURES

FIG. 1 shows Gibbs free energy changes for oxidation reactions of Mo with H₂O, N₂O, O₂ and O₃ at 0-500° C.

FIG. 2 shows Gibbs free energy changes for etching reactions of MoO₂ and MoO₃ with NbCl₅ at 0-500° C.

FIG. 3 shows a) Saturation curve of EPC with respect to O₂ using 4 s NbCl₅ pulses and b) Saturation curve of EPC with respect to NbCl₅ using 3 s O₂ pulses at 300° C.

FIG. 4. Shows thickness of the etched layer after 20-200 Atomic Layer Etch (ALEt) cycles at 300° C.

FIG. 5. Shows a) EPC at different temperatures using (4/1/3/1) s cycles, b) EPC as function of O₂ pulse length at different temperatures with (4/1/x/1) s cycles.

FIG. 6. Shows X-ray diffractograms of unetched Mo film and films etched at 300, 350, and 400° C.

FIG. 7 shows in part a) Roughness (root mean square) of Mo films etched for 0-200 cycles using NbCl₅ and O₂. AFM maps of b) an unetched film and c) a film etched for 200 cycles. Scale of the AFM images is 1×1 μm.

FIG. 8 shows SEM images of Mo films a) before etching and b) after 200 etch cycles at 300° C.

FIG. 9 shows resistivity of the Mo films before and after etching as a function of film thickness.

FIG. 10. Shows mixed phase Ta film surface after a) 20, b) 25 (sample edge), c) 25 (middle of sample), d) 30 cycles of NbCl₅ and H₂O at 350° C.

FIG. 11 shows an X-ray diffraction (XRD) of mixed phase Ta films etched with different numbers of (2/1/1/1) s cycles of NbCl₅ and H₂O.

FIG. 12 shows XRD of a Ta film before and after being heated to 350° C. for 1 h in vacuum.

FIG. 13 shows Atomic Force Microscopy (AFM) maps and line scans of mixed phase Ta films etched for a) 30 and b) 50 cycles at 350° C. using NbCl₅ and H₂O.

FIG. 14 shows SEM images of a-Ta etched at 300 and 350° C.

FIG. 15 shows XPS of the Ta 4f peaks for Ta films a) as received with native oxide, b) after etching with NbCl5, c) after stripping the native oxide with sputtering, d) after oxidizing the cleaned surface with O₂, e) after etching the oxidized surface with NbCl₅, and f) after additional NbCl₅ pulses.

FIG. 16 shows Gibbs free energy changes for etching different oxides with NbCl₅ as a function of temperature.

FIG. 17 shows dependence of etch per cycle (EPC) at 325° C. on a) NbCl₅ pulse length, when the purge time is 3 s and b) purge length, when the NbCl₅ pulse length is 1 s.

FIG. 18 shows the Arrhenius dependence of EPC on temperature.

FIG. 19 shows quadrapole mass spectrometer (QMS) analysis of NbCl₅ fragments and etch products of Ta₂O₅ during etching at 325° C.

FIG. 20 shows AFM maps of a) an unetched film and b) a film where 30 nm have been etched with NbCl5 at 325° C. c) Rq of the films as a function of etch amount.

FIG. 21 shows a) EPC as at different temperatures for various oxide materials and b) approximate EPC at the middle of the films for etching TiO₂ with NbCl₅.

FIG. 22 shows a) SEM image of an Al₂O₃ film etched at 400° C. with NbCl₅ and b) a closeup of one of the features on the surface.

FIG. 23 shows SEM images of the FIB pattern on a Ta₂O₅/Al₂O₃ double layer a) before and b) after etching with 2500×(1/3) s cycles of NbCl₅. c-f) show closeups of the overhang structures before and after etching.

FIGS. 24 and 25 show embodiments of methods according to the present disclosure.

FIG. 26 shows an embodiment of a system according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In some embodiments, terms such as “etchant reactant”, “reactant”, and “etchant” can refer generally to at least one compound that participates in an etching reaction that etches a target layer on a substrate.

In some embodiments, “layer” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation process or sequence, and/or functions or purposes of the adjacent films or layers.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

In some cases, the term “precursor” can refer to a compound that participates in a chemical reaction that produces another compound, and particularly to a compound that constitutes a film matrix or a main skeleton of a film; the term “reactant” can be used interchangeably with the term “precursor”. The term “inert gas” can refer to a gas that does not take part in a chemical reaction and/or does not become a part of a film matrix to an appreciable extent. Exemplary inert gases include noble gasses, such as helium, argon, and any combination thereof. In some cases, an inert gas can include nitrogen and/or hydrogen. Purge gasses can comprise inert gasses.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; or combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

By way of example, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition or etching process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Described herein are methods of etching. In some embodiments, presently disclosed methods comprise pulsed etching. In some embodiments, presently disclosed methods comprise atomic layer etching. An embodiment of the presently disclosed methods comprises providing a substrate to a reaction chamber. The substrate comprises an etchable layer. The etchable layer comprises a metal. A method according to an embodiment of the present disclosure comprises executing a cyclical etching process. The cyclical etching process comprises a plurality of etching cycles. Ones from the plurality of etching cycles comprise a conversion reactant pulse and a volatilization reactant pulse. The volatilization reactant pulse comprises exposing the substrate to a volatilization reactant. The conversion reactant pulse comprises exposing the substrate to a conversion reactant. Thus, the etchable layer is etched.

In some embodiments, the conversion reactant modifies a surface of the etchable layer. In some embodiments, the resulting modified surface is then etched by contacting the surface with the volatilization reactant. Doing so sequentially allows digitally etching the etchable layer.

In some embodiments, the conversion reactant pulse precedes the volatilization reactant pulse. In some embodiments, the volatilization reactant pulse precedes the conversion reactant pulse.

It shall be understood that in some embodiments, the conversion reactant pulse and the volatilization reactant pulse are at least partially non-overlapping. In some embodiments, the conversion reactant pulse and the volatilization reactant pulse do not overlap. In some embodiments, adjacent conversion reactant pulses and volatilization reactant pulses are separated by purges.

While the presently disclosed methods are generally described as a cyclical process, co-flow of conversion reactant and volatilization reactant can be done too, in some embodiments.

In other words, in some embodiments, conversion reactant and volatilization reactant are provided together to the reaction chamber. This can advantageously enhance throughput though such processes do not feature self-limiting steps.

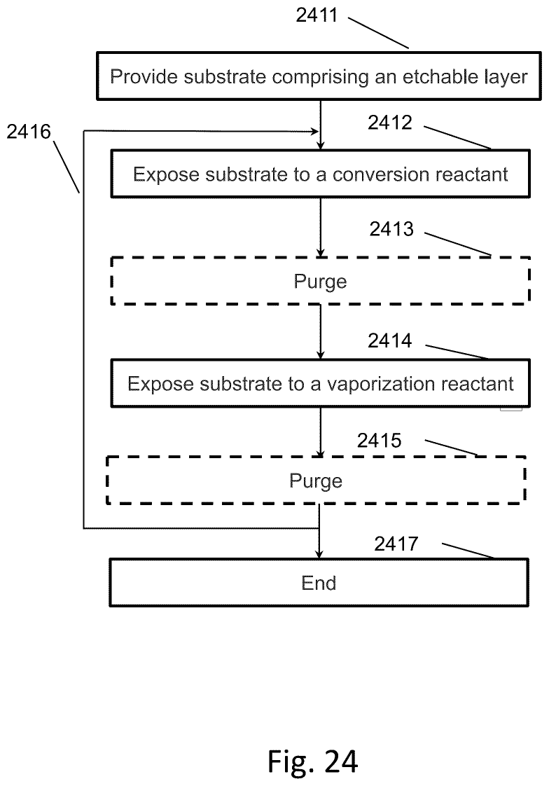

Referring to FIG. 24, described herein is an embodiment of a method according to the present disclosure. The method comprises a step 2411 of providing a substrate to a reaction chamber. Then, the method comprises executing a plurality of etching cycles 2416. Ones from the plurality of etching cycles comprise, in the order given, a step 2412 of exposing the substrate to a conversion reactant, an optional purge 2413, a step 2414 of exposing the substrate to a volatilization reactant, and another optional purge 2415. Alternatively, the step of exposing the step 2412 of exposing the substrate to a conversion reactant can be preceded by the step 2414 of exposing the substrate to a volatilization reactant as described herein. After a suitable amount of etching cycles have been carried out, the method ends.

Described herein is an embodiment of a method of selectively etching. The method comprises providing a substrate to a reaction chamber. The substrate comprises an etchable layer. The etchable layer can comprise a metal. The substrate further comprising a second layer. The method further comprises executing an etching process that comprises sequentially exposing the substrate to a vaporization reactant and a purge gas. The vaporization reactant can comprise a metal halide. Thus, the etchable layer is etched while the second layer is not substantially etched during the cyclical etching process.

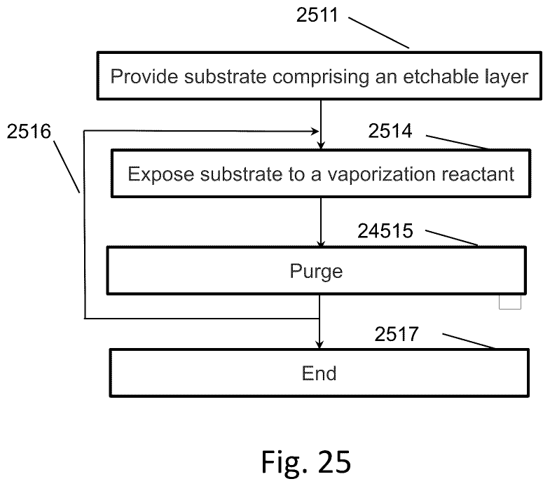

Referring to FIG. 25, described herein is another embodiment of a method according to the present disclosure. The method comprises a step 2511 of providing a substrate to a reaction chamber. Then, the method comprises executing a plurality of etching cycles 2516. Ones from the plurality of etching cycles comprise, in the order given, a step 2514 of exposing the substrate to a volatilization reactant, and a purge 2515. Alternatively, the purge 2515 can precede the step 2514 of exposing the substrate to a volatilization reactant as described herein. After a suitable amount of etching cycles have been carried out, the method ends.

In some embodiments, the volatilization reactant as described herein comprises a metal halide. In some embodiments, the metal halide is selected from a metal fluoride, a metal chloride, a metal bromide, and a metal iodide.

In some embodiments, the volatilization reactant comprises a transition metal halide.

In some embodiments, volatilization reactant comprises niobium pentachloride (NbCl₅). In some embodiments, the volatilization reactant comprises niobium pentafluoride. In some embodiments, the volatilization reactant comprises niobium pentabromide. In some embodiments, the volatilization reactant comprises niobium pentaiodide. In some embodiments, the volatilization reactant comprises a niobium halide. In some embodiments, the volatilization reactant comprises a niobium pentahalide.

In some embodiments, the volatilization reactant comprises vanadium pentafluoride. In some embodiments, the volatilization reactant comprises vanadium pentachloride. In some embodiments, the volatilization reactant comprises vanadium pentabromide. In some embodiments, the volatilization reactant comprises vanadium pentaiodide. In some embodiments, the volatilization reactant comprises a vanadium halide. In some embodiments, the volatilization reactant comprises a vanadium pentahalide.

In some embodiments, the volatilization reactant comprises molybdenum pentafluoride. In some embodiments, the volatilization reactant comprises molybdenum pentachloride. In some embodiments, the volatilization reactant comprises molybdenum pentabromide. In some embodiments, the volatilization reactant comprises molybdenum pentaiodide. In some embodiments, the volatilization reactant comprises a molybdenum halide. In some embodiments, the volatilization reactant comprises a molybdenum pentahalide.

In some embodiments, the volatilization reactant comprises molybdenum hexafluoride. In some embodiments, the volatilization reactant comprises molybdenum hexachloride. In some embodiments, the volatilization reactant comprises molybdenum hexabromide. In some embodiments, the volatilization reactant comprises molybdenum hexaiodide. In some embodiments, the volatilization reactant comprises a molybdenum hexahalide.

In some embodiments, the metal comprised in the volatilization reactant is selected from the group consisting of titanium, vanadium, chromium, zirconium, molybdenum, hafnium, and tungsten.

In some embodiments, the volatilization reactant comprises one or more post transition metals, such as Al, Ga, In, Sn, or Bi.

In some embodiments, the volatilization reactant comprises tungsten. In some embodiments, the volatilization reactant comprises tungsten hexafluoride. In some embodiments, the volatilization reactant comprises tungsten hexachloride. In some embodiments, the volatilization reactant comprises tungsten hexabromide. In some embodiments, the volatilization reactant comprises tungsten hexaiodide. In some embodiments, the volatilization reactant comprises a tungsten halide. In some embodiments, the volatilization reactant comprises a tungsten hexahalide.

In some embodiments, the volatilization reactant comprises a metal center. The metal center can have any oxidation state, such as +3, +4, +5, +6, +7, and +8.

In some embodiments, the conversion reactant as described herein comprises an oxygen reactant. An oxygen reactant can comprise oxygen.

In some embodiments, the oxygen reactant comprises O₂.

In some embodiments, the oxygen reactant is selected from the list consisting of H₂O, N₂O, O₂ and O₃.

In some embodiments, the oxygen reactant comprises an oxygen plasma. Suitable plasmas include direct, indirect, and remote plasmas. In some embodiments, the plasma is a capacitive plasma, and inductively coupled plasma, or a microwave plasma. In some embodiments, the plasma is generated using a plasma gas comprising a noble gas and an oxygen reactant as disclosed herein. Suitable noble gasses include He, Ne, Ar, Kr, and Xe.

In some embodiments, the oxygen reactant is selected from the group consisting of H₂O, H₂O₂, N₂O, NO, NO₂, NO₃, CO, CO₂, O₂, and O₃.

In some embodiments, the oxygen reactant comprises an alcohol. The alcohol can comprise one or more alcohol groups. In some embodiments, the oxygen reactant comprises a C1 to C6 linear or branched alcohol, such as methanol, ethanol, isopropanol, and n-butanol. In some embodiments, the oxygen reactant comprises a C1 to C6 linear or branched diol, such as ethane-1,2-diol.

In some embodiments, the etchable layer comprises at least 90, 95, 98, 99, 99.5, 99.8, or 99.9 atomic percent of the metal.

In some embodiments, the etchable layer substantially consists of the metal.

In some embodiments, the metal comprises a transition metal.

In some embodiments, the etchable layer comprises one or more of a transition metal nitride, boride, or phosphide. In some embodiments, the etchable layer comprises an etchable material that can be oxidized using an oxygen reactant, such as an oxygen reactant mentioned in the present disclosure.

In some embodiments, the etchable layer comprises a transition metal nitride. In some embodiments, the transition metal nitride comprises one or more of tantalum nitride, titanium nitride, and zirconium nitride.

In some embodiments, the transition metal comprises at least one of tantalum and molybdenum. Suitably, the transition metal can form a volatile compound with the volatilization reactant. Possible volatile compounds include chlorides and oxychlorides.

In some embodiments, the etchable layer comprises at least one of Ta₂O₅, TiO₂ or ZrO₂.

In some embodiments, the cyclical etching process is carried out thermally. In other words, and in some embodiments, the cyclical etching process does not involve generating a plasma or exposing the substrate to plasma-generated species.

In some embodiments, the substrate further comprises a second layer. In some embodiments, the second layer is not substantially etched during the cyclical etching process. In some embodiments, the second layer is etched slower than the etchable layer. In some embodiments, the etchable layer is etched at least 2 times faster than the second layer. In some embodiments, the etchable layer is etched at least 5 times faster than the second layer. In some embodiments, the etchable layer is etched at least 10 times faster than the second layer. In some embodiments, the etchable layer is etched at least 20 times faster than the second layer. In some embodiments, the etchable layer is etched at least 50 times faster than the second layer. In some embodiments, the etchable layer is etched at least 100 times faster than the second layer.

In some embodiments, the second layer comprises at least one of HfO₂, SiO₂, Al₂O₃, and TiN. In some embodiments, the second layer comprises a material that forms a non-volatile material when exposed to the volatilization reactant. In some embodiments, the second layer comprises a material that is substantially unreactive with the volatilization reactant. In some embodiments, the second layer comprises a material that forms a passive layer when exposed to the volatilization reactant.

A cyclical etching process according to an embodiment of the present disclosure can be carried out at any suitable temperature. In some embodiments, the cyclical etching process is carried out at a temperature of at least 250 to at most 450° C., or of at least 200 to at most 500° C.

In some embodiments, the cyclical etching process is carried out at a pressure of at least 0.01 mbar to at most 1 bar, or at a pressure of at least 0.1 mbar to at most 0.1 bar, or at a pressure of at least 1 mbar to at most 10 mbar. In some embodiments, the cyclical etching process is carried out at a pressure of 10 mbar.

In some embodiments, the volatilization reactant is stored in a reactant source comprising a heating element. In other words, and in some embodiments, the volatilization reactant can be stored in a heated source. For example, the heated source may be maintained at a temperature of at least 50° C. to at most 200° C., or of at least 60° C. to at most 150° C., or of at least 70° C. to at most 100° C., e.g., at a temperature of 80° C.

In some embodiments, the volatilization reactant pulse is followed by a by a first purge.

In some embodiments, the conversion reactant pulse is followed by a second purge.

Purges can comprise contacting the substrate with an inert gas. Purges can be effected by alternating gas flows, or by moving the substrate through an inert gas curtain.

In some embodiments, purging can comprise subjecting the substrate to a constant flow of inert gas. During a volatilization reactant pulse, the inert gas stream can be routed through a volatilization reactant source to entrain volatilization reactant. During a conversion reactant pulse, the inert gas stream can be routed through a conversion reactant source to entrain conversion reactant. During purges, the inert gas stream can bypass the reactant sources such that no reactant is entrained. Suitable inert gas streams can comprise a noble gas, such as He, Ne, Ar, Xe, or Kr. In some embodiments, the inert gas stream comprises N₂.

Further described herein is a system that comprises a reaction chamber, a substrate support, and a controller. The controller is programmed and/or configured for causing the system to execute a method as described herein. In some embodiments, the system does not comprise a plasma source.

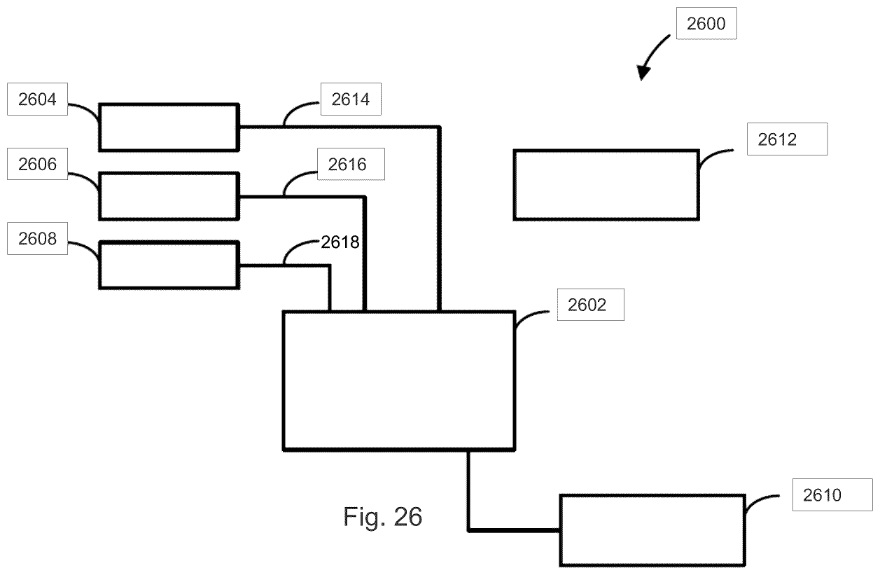

Referring to FIG. 26, further described herein is a system 2600 that is configured and arranged for carrying out an embodiment of a method as described herein.

In the illustrated example, the system 2600 includes one or more reaction chambers 2602, a conversion reactant gas source 2604, a volatilization reactant gas source 2606, a purge gas source 2608, an exhaust source 2610, and a controller 2612. Of course, other gas sources can be present, in some embodiments. For example, a system 2600 can comprise all of a conversion reactant gas source 2604, a volatilization reactant gas source 2606 source, a purge gas source 2608, and further gas sources. The reaction chamber 2602 can include any suitable reaction chamber. For simplicity, the system 2600 is described referring only to a generic conversion reactant gas source 2604 and a generic volatilization reactant gas source 2606.

The conversion reactant gas source 2604 can include a vessel and one or more precursors as described herein-alone or mixed with one or more carrier (e.g., inert) gases. The volatilization reactant gas source 2606 can include a vessel and one or more reactants as described herein-alone or mixed with one or more carrier gases. The purge gas source 2608 can include one or more purge gases as described herein. Although illustrated with three gas sources 2604-2608, the system 2600 can include any suitable number of gas sources. The gas sources 2604-2608 can be coupled to reaction chamber 2602 via lines 2614-2618, which can each include flow controllers, valves, heaters, and the like. The exhaust 2610 can include one or more vacuum pumps.

The controller 2612 includes electronic circuitry and software to selectively operate valves, manifolds, heaters, pumps and other components included in the system 2600. Such circuitry and components operate to introduce precursors, reactants, and purge gases from the respective sources 2604-2608. The controller 2612 can control timing of gas pulse sequences, temperature of the substrate and/or reaction chamber, pressure within the reaction chamber, and various other operations to provide proper operation of the system 2600. The controller 2612 can include control software to electrically or pneumatically control valves to control flow of precursors, reactants and purge gases into and out of the reaction chamber 2602. The controller 2612 can include modules such as a software or hardware component, e.g., a Field-Programmable Gate Array (FPGA) or Application-Specific Integrated Circuit (ASIC), which performs certain tasks. A module can advantageously be configured to reside on the addressable storage medium of the control system and be configured to execute one or more processes.

Other configurations of the system 2600 are possible, including different numbers and kinds of reactant sources and purge gas sources. Further, it will be appreciated that there are many arrangements of valves, conduits, precursor sources, and purge gas sources that may be used to accomplish the goal of selectively feeding gases into the reaction chamber 2602. Further, as a schematic representation of a system, many components have been omitted for simplicity of illustration, and such components may include, for example, various valves, manifolds, purifiers, heaters, containers, vents, and/or bypasses.

During operation of the reactor system 2600, substrates, such as semiconductor wafers (not illustrated), are transferred from, e.g., a substrate handling system to reaction chamber 2602. Once substrate(s) are transferred to the reaction chamber 2602, one or more gases from the gas sources 2604-2608, such as precursors, reactants, carrier gases, and/or purge gases, are introduced into reaction chamber 2602.

Further described herein is a method of selectively depositing a layer. The method comprises providing a substrate to a reaction chamber. The substrate comprises a first surface and a second surface. The method further comprises executing a cyclical deposition process. The cyclical deposition process comprises a plurality of cycles. Ones from the plurality of cycles comprise a deposition sub step and an etching sub step. The deposition sub step comprises contacting the substrate with one or more precursors and reactants to selectively form a deposited layer on the first surface, and not or to a lesser degree on the second surface. The deposition sub step can comprise any suitable deposition technique, such as atomic layer deposition or chemical vapor deposition. The etching sub step comprises contacting the substrate with one or more etchants, conversion reactants, volatilization reactants, and/or the like. The etching sub step can comprise any suitable etch, such as a continuous etch, a pulsed etch, and an atomic layer etch. The etching sub step can comprise executing an etching process according to an embodiment of the present disclosure. By sequentially and cyclically depositing and etching, selectivity can be improved, e.g., by removal of nuclei from the second surface.

In an embodiment of the present disclosure, an atomic layer etching process for metallic Mo and Ta is described. O₂ may be employed to oxidize the surface layer of the metal. NbCl₅ may be employed to volatilize the oxide layer by producing metal chlorides or oxychlorides. In an embodiment, etching of Mo was demonstrated at temperature range of 250-400° C. The O₂ pulse length was found to not saturate, but compromise between etch per cycle (EPC) and overall process time was found at 3 s O₂ pulse. 1.2-4.0 A EPC was observed with this O₂ pulse length at 300-400° C. Roughness of the Mo films increased slightly during etching, but no contamination of the films was observed. Resistivity of the films increased slightly as they became thinner, but this is explainable by thin film effects. Ta was found to etch at different rate depending on the phase composition of the metal, with f3-Ta etching at a higher EPC than a-Ta.

Initial studies found EPC of 2.0 and 4.0 Angstrom for etching a-Ta at 300 and 350° C., respectively. Some diffusion of oxygen from the surface oxide into the metal at the etching temperature was observed, but no other contaminants were evident.

Advantageously, embodiments according to the present disclosure may provide milder alternatives to previously demonstrated O₃ in oxidation/chlorination based ALEt of Mo. As far as the inventors' knowledge, it is demonstrated for the first time an atomic layer process for etching metallic tantalum. In comparison to reactive ion etch (RIE), the disclosed methods herein demonstrate isotropic etching with minimal surface damage to the etching target or surrounding materials, while avoiding the problems associated with wet etching, such as collapse of 3D structures due to capillary forces.

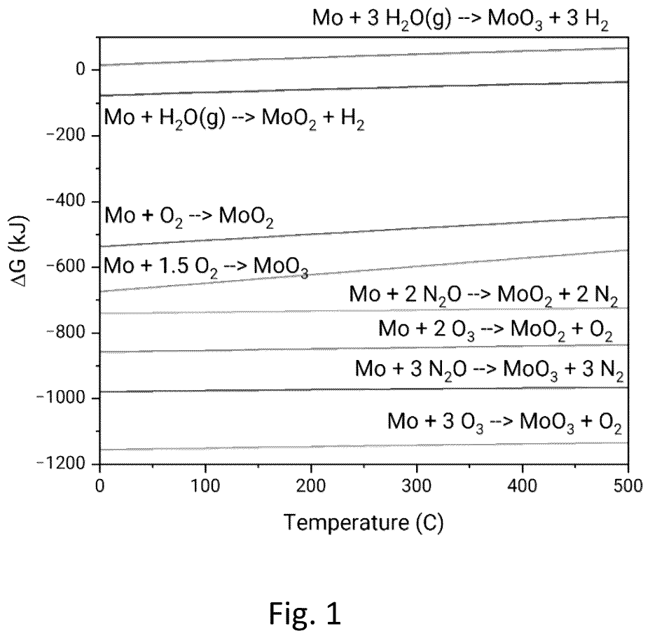

In an embodiment of the present disclosure, HSC chemistry software package was used to evaluate the thermodynamic feasibility of the oxidation and etching half reactions for Mo. Gibbs free energies for the oxidation reactions of Mo into MoO₂ and MoO₃ with H₂O, O₂, N₂O, and O₃ were calculated at the temperature range 0-500° C. (FIG. 1).

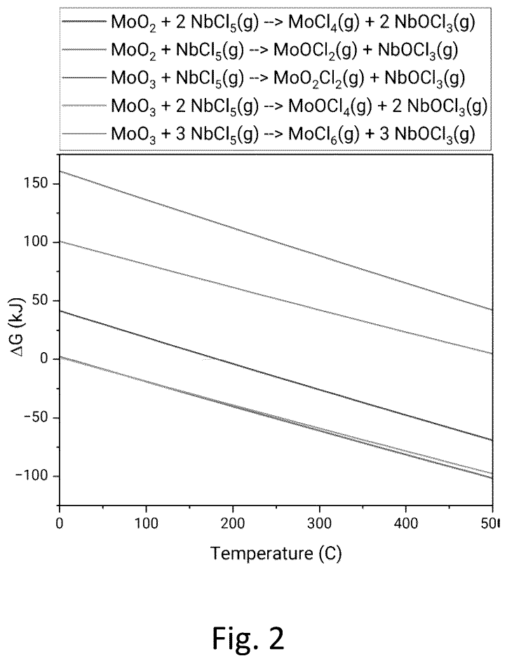

It can be seen that the Gibbs energies of oxidation are not significantly affected by temperature, and it is thermodynamically feasible to oxidize Mo to MoO₂ and MoO₃ with O₂, O₃, and N₂O. With H₂O, only oxidation to MoO₂ is thermodynamically favored. Gibbs free energy changes of the etching reactions of MoO₂ and MoO₃ with NbCl₅ by producing molybdenum chlorides and oxychlorides were calculated (FIG. 2). Conversion of MoO₃ to MoO₂Cl₂ or MoOCl₄ is favorable at the whole temperature range and conversion of MoO₂ to MoCl₄ is favorable beginning at 200° C.

In an embodiment, Ta films grown on Si with filtered cathodic arc deposition (FCAD) were employed as a substrate. In another embodiment, ALD Mo films grown on 100 nm thermal SiO₂ were employed as a substrate.

The films were etched in an F-120 ALD reactor by consecutively pulsing NbCl₅ and O₂/H₂O, each pulse followed by purging with N₂ (99.999%). The pulse and purge lengths of ALEt cycles are denoted (t1/t2/t3/t4), where t1 is the NbCl₅ pulse length, t2 is a purge, t3 is the oxidant pulse length, and t4 a purge. NbCl₅ was evaporated in a glass boat inside the reactor at 80° C. H₂O and O₂ were delivered from external lines controlled by needle valves.

Film thicknesses were measured before and after etching using XRR. The value after etching was verified by measuring EDS and calculating the film thickness with GMRfilm software.

In vacuo XPS studies were done using a Beneq TFS200 ALD reactor and PREVAC XPS system. NbCl₅ was evaporated with 90° C. as the source temperature.

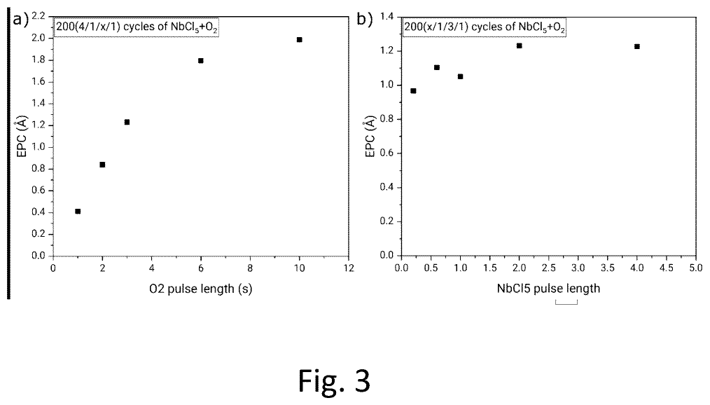

In an exemplary embodiment, Mo films were first subjected to NbCl₅ vapor alone to verify that the etchant does not etch the films by itself. After 1000 cycles of (1/3) s at 300-400° C. the etched thickness was 1-3 nm, indicating no significant etching of the metal. Next, O₂ pulses were introduced to form the etching cycle. Using (4/1/x/1) s cycles, O₂ pulse time was varied, and it was found that the pulse does not saturate even at 10 s long pulses, but the EPC increase slows down (FIG. 3). The oxide layer grows by diffusion of O₂ into the interface, which is driven by the concentration gradient. Reaction rate should be proportional to the O₂ concentration on the surface. Measuring the film resistance at several points along the surface with a four-point probe showed that the etching is proceeding faster at the O₂ inlet side, which would indicate that O₂ is consumed before it reaches the end of the film, but this seems unlikely considering the high dosage. To optimize process time, a 3 s O₂ pulse was chosen to study the saturation of NbCl₅.

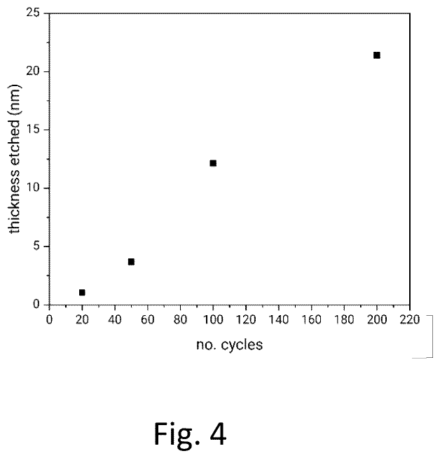

It was seen that with 3 s O₂ pulses, NbCl₅ saturates fully after 2 s. Using ALEt cycles of (4/1/3/1) s, the linearity of etching was studied (FIG. 4). It was seen that the etching is slower at the beginning, but proceeds fairly linearly after 20 cycles.

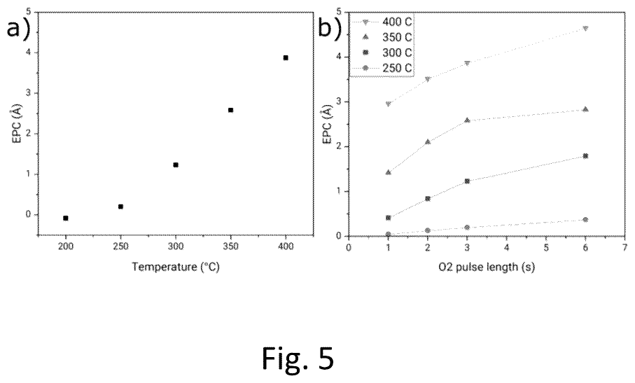

Next, the etching was studied with (4/1/3/1) s cycles at the temperature range 200-400° C. It is seen that EPC is highly dependent on the etching temperature (FIG. 5, part a). Studies on the O₂ pulse saturation were done at 250-400° C. (FIG. 5, part b). It is seen that the EPC is not saturating with 1-6 s O₂ pulses.

In vacuo XPS was used to study the etching process at 300° C. The native oxide surface of the films was seen to consist of multiple oxidation states of Mo. After etching with NbCl₅, the highest oxidation states were removed, but peaks appeared at intermediate positions. These are interpreted to be from chlorides or oxychlorides on the surface. This was supported by the observation that there is considerable amount of Cl on the surface. Additional NbCl₅ pulses did not alter the XPS spectrum.

Oxidizing the surface with O₂ removed much of the Cl and the Mo peaks of chlorides or oxychlorides were attenuated as well.

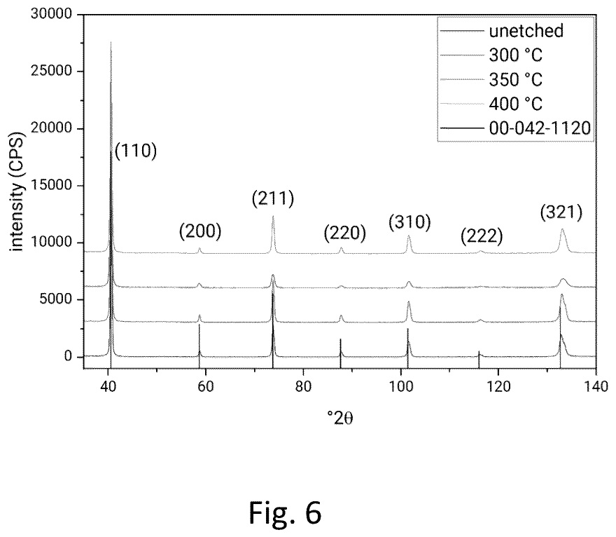

Grazing incidence X-ray diffraction was done on unetched Mo film and films etched at 300-400° C. The as-received unetched films were cubic Mo, and the etching did not affect the crystalline characteristics (FIG. 6).

EDS measurements of partially etched films showed Si, O and Mo on the surface, and occasionally C, which is most likely from atmospheric contamination of the samples. No Nb or Cl was detected.

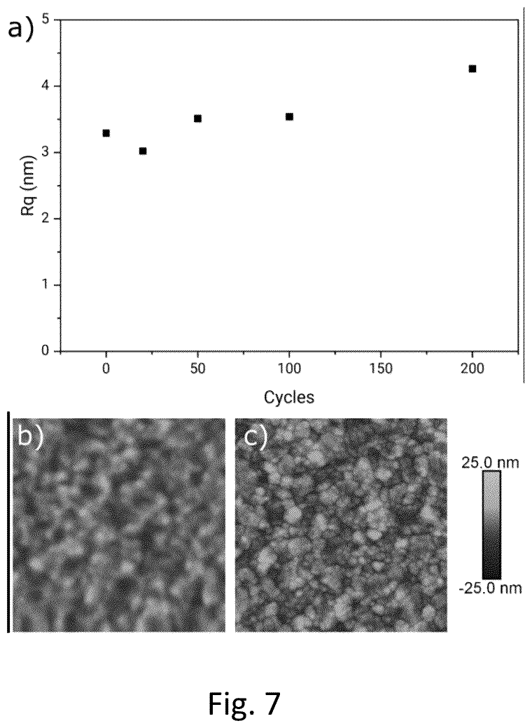

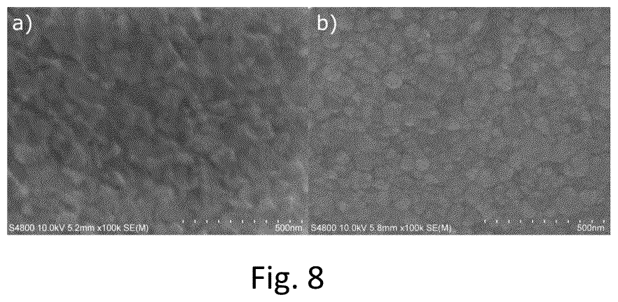

AFM was used to study films etched for 20-200 cycles at 300° C. From FIG. 7, it can be seen that the roughness of these films increased slightly during etching. The AFM map of the sample etched for 200 cycles shows that the grains of material become more distinct, which indicates that there is some preferential etching at the grain boundaries. Without the present disclosure being limited by any particular theory or mode of operation, it is believed that this is most likely due to enhanced oxygen diffusion along the grain boundaries. The pronounced etching at the grain boundaries is evident in FIG. 7c. SEM images of the same samples in FIG. 8 show also show the change in the surface.

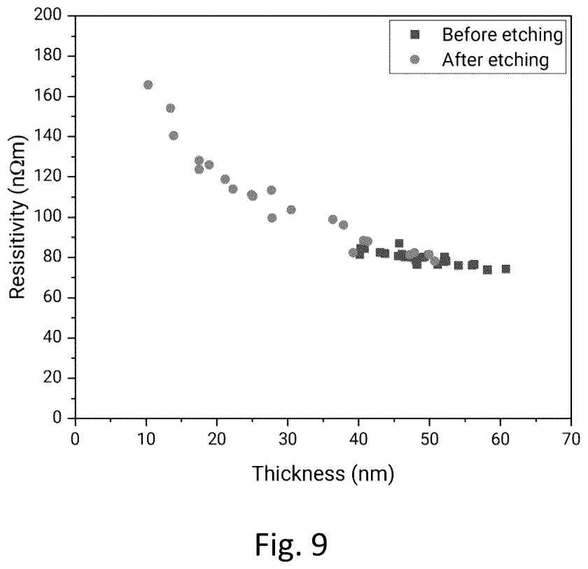

Resistivity of the films is seen to change with film thickness, becoming larger at thicknesses below 30 nm (FIG. 9). This might be caused by selective etching at the grain boundaries, but thin film effects are also expected at these thicknesses. Bulk resistivity of Mo is 5.34 μΩcm, whereas the resistivity of these films as received was around 8 μΩcm. ALD grown Mo films have previously shown increases in resistivity at film thicknesses below 20 nm, and a sharp increase when approaching the mean free path of electron in Mo (11.2 nm). 1 In FIG. 9, it seems that the resistivities of the etched and unetched films follow a similar trend—at least above about 40 nm thickness.

The Ta films were characterized using XRD. It was seen that most of the films were a mixture of α-Ta and β-Ta, but a few samples were mainly α-Ta. Etching the mixed phase films with only NbCl₅ with 1000 (1/3) s cycles resulted in some etching, with a spotty surface visible with SEM. For the sample etched at 300° C., the change was barely visible but was more prominent for samples etched at 350 and 400° C. Due to the rough morphology, unambiguous modelling of the XRR measurements post-etch was not possible.

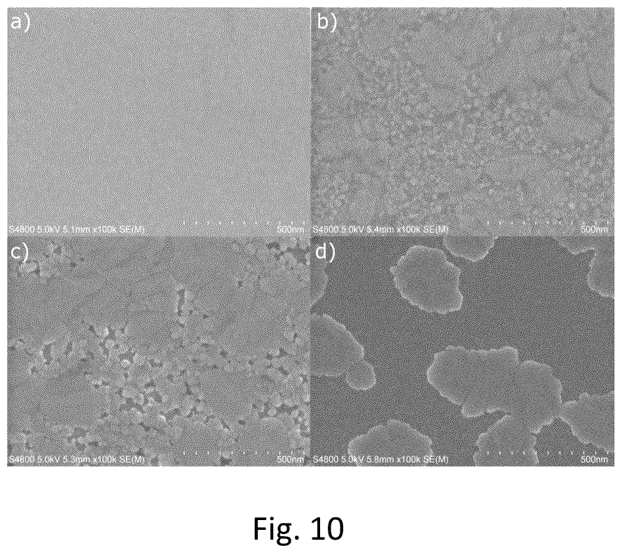

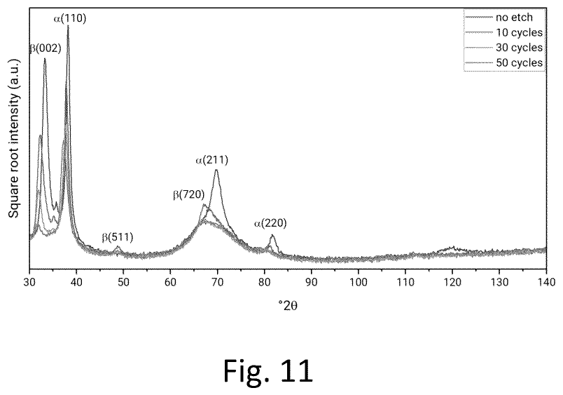

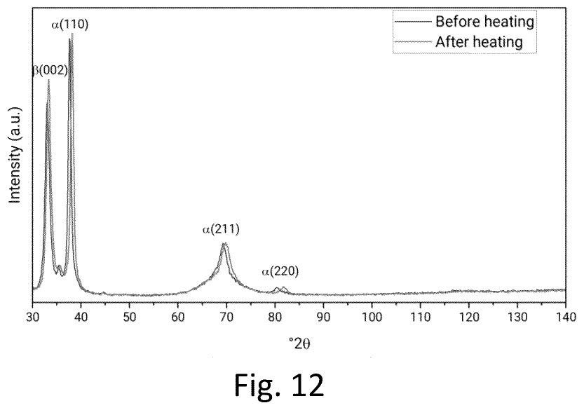

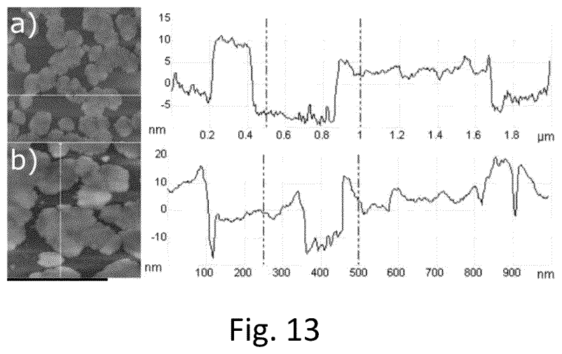

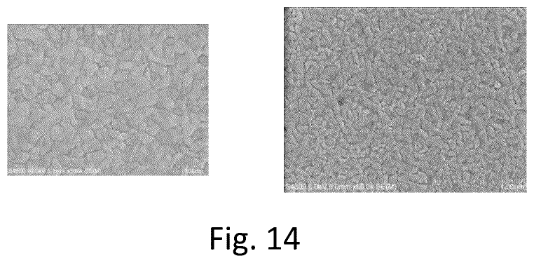

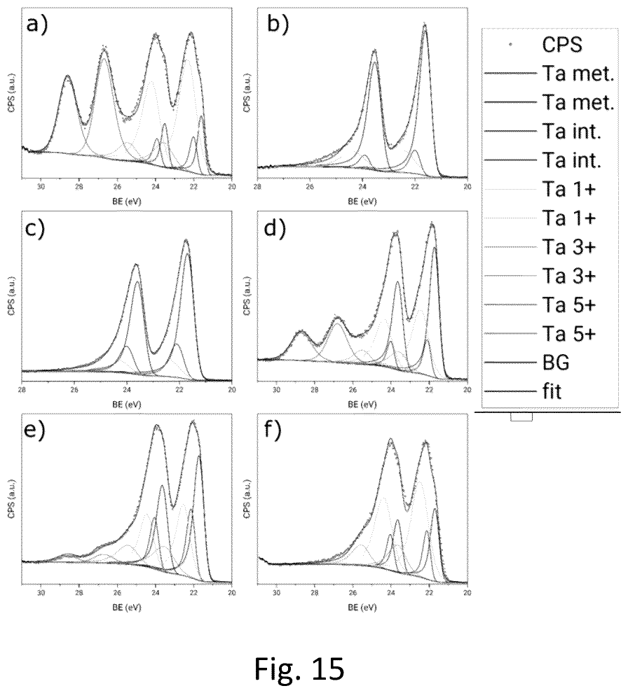

Using H₂O as an oxidant resulted in much faster etching, but the changes in morphology were also intensified. FIG. 10 shows the development of the surface structures with different etch cycle numbers.

XRD of the etched films show that the reflections of the β-phase are slowly diminishing as the etching proceeds further, and the peaks are also shifting to lower angles. The shift is likely caused by oxygen dissolution into the Ta at elevated temperatures. A sample was also heated to 350° C. for 1 h to see if the oxygen dissolution is causing a phase transformation from β to α. In the resulting XRD, one sees the shift of all peaks by about 1°2θ, but the peak intensities do not change significantly. This indicates that the disappearance of the β-phase is caused by the etching process rather than a phase transformation.

AFM measurements of the films etched to different degrees were conducted and it was seen that the etching is indeed proceeding faster at the low-lying areas and the step height of the remaining islands is increasing. Step height of the islands was around 15-20 nm after etching for 30 cycles and 20-30 nm after etching for 50 cycles.

The phase difference seems to be the key factor in explaining the differential etch rates at the surface. The two phases should be chemically very similar, but it is possible that the phase is affecting the oxidation kinetics through e.g. surface bond density.

O₂ was also used for ALEt of the mixed phase film to see if the additional oxidative power could make the two phases etch at similar rates. The results were similar to the etching with H₂O.

The few samples that were almost all α-Ta were used in comparative studies. Using NbCl₅ and O₂, there was a clear difference in the film morphology, as the films are continuous after etching. XRR measurements show some inconsistencies in the etch rates and it was deduced that the etching starts slowly, like with Mo. 40 cycles of NbCl₅ alone were used in this case before the ALEt to remove the native oxide and make sure that EPC with different cycle numbers is comparable. The alpha Ta samples ran out before proper process optimization could be done, but at least 2 and 4 Å EPC could be achieved at 300 and 350° C., respectively.

During the XPS studies, it was found that there was a Nb₂O₅ ALD component to the etching process in the specific reactor when using H₂O as the oxidant. The reason for this is presumed to be the large reactor surface area generating NbOCH₃ in situ from the NbCl₅ and H₂O adsorbing and reacting on the reactor walls. NbOCl₃ is known to be a viable Nb₂O₅ ALD precursor. To avoid the Nb₂O₅ deposition, O₂ was used as an oxidant for the experiments. The experiments were conducted with 350° C. as the etching temperature.

Starting with a sputter cleaned metal surface, it could be seen that the Ta was mainly in the TaO oxidation state, with some Ta+ mixed in. This was then oxidized with 3 (2/2) s pulses of O₂ and emergence of Ta5+ and Ta3+ peaks was seen. Etching the sample with 4 (4/5) s pulses of NbCl₅ resulted in mostly metallic surface, with some Ta5+ and Ta3+ still visible in the spectrum. Further 4 (4/5) s NbCl₅ pulses completely removed the Ta5+ but some Ta3+ was still seen.

In another experiment, the native oxide was subjected to 20 (4/5) s pulses of NbCl₅ and the resulting Ta XPS spectrum was nearly identical to the sputtered film spectrum. Some Cl was also seen on the film surface after the etching pulses, but this was very minor and was removed by an O₂ pulse.

Thus, exemplary embodiments of the present disclosure directed to a combination of NbCl₅ with O₂ in ALEt present a new etching process that can be used to etch Mo and Ta. Mo can be etched in a controlled manner with minimal contamination of the films and only slight alteration to the film morphology. Ta can be etched, but the process is highly sensitive to the phase composition of the metal film, and mixed phase films show highly different etch rates. Single phase films can be etched uniformly in a controlled manner but currently we lack the samples to study this in depth. Some evidence for dissolution of O into the Ta films was seen.

In an embodiment, O₂ is used to oxidize a Ta metal surface, after which NbCl₅ is pulsed onto the surface to etch the produced oxides by creating volatile chlorides and oxychlorides. Suitable metal surfaces include metallic tantalum and metallic molybdenum. The Mo etching proceeds in a controllable manner with minimal contamination or alteration of film properties. Ta etch rates are high and dependent on the phase composition of the metal, and etching of beta-Ta proceeds much faster than the etching of alpha-Ta.

In an embodiment, NbCl₅ was used as an etchant vapour to etch Ta₂O₅, TiO₂ and ZrO₂ films using gas phase pulsed etching, i.e., using a process in which the etchant vapour is provided in pulses, i.e., it is intermittently interrupted by purge gas pulses. Selectivity towards HfO₂, SiO₂, Al₂O₃, and TiN was demonstrated at the temperature range 300-400° C. Etch per cycle (EPC) of the materials was dependent on the temperature, and reached 2.8, 1.1, and 3.7 A for Ta₂O₅, ZrO₂, and TiO₂, respectively. In Ta₂O₅ etching, the purging step after the etchant pulse was found to have significant effect on the EPC, which almost doubled when purge time was extended from 1 to 3 s. Roughness of the Ta₂O₅ films increased from 0.2 nm to 1.4 nm when etching up to 30 nm but remained constant with further etching. No significant metallic residues were detected in the etched films, but some Cl was detected with in situ XPS. Suitability of the method for selective isotropic etching of 3D structures was demonstrated with a patterned Al₂O₃ on Ta₂O₅ structure.

Although thermal gas phase etching of Ta₂O₅ has been demonstrated before, a single component high selectivity etch according to an embodiment of the present disclosure has not been developed before. The thermal activation provides isotropic etching and avoids damage caused by plasma processing. The use of chloride etchant rather than fluoride-based one improves selectivity towards materials, such as SiO₂. In addition, the pulsing of the etchant gas allows for digital control of the etch depth.

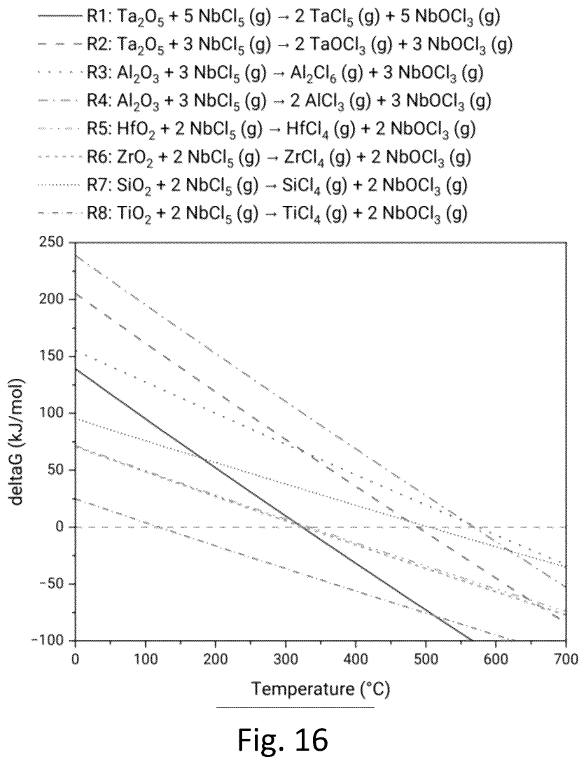

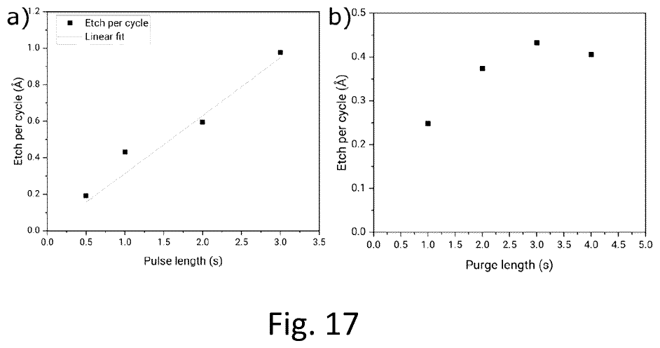

In an embodiment, the thermodynamic feasibility of different etching reactions with NbCl₅ was studied using HSC Chemistry software package by calculating the Gibbs free energy changes for different reactions at relevant temperatures (FIG. 1). The etching reactions of Ta₂O₅, ZrO₂, and HfO₂ become thermodynamically favorable at temperatures slightly over 300° C., whereas etching of TiO₂ becomes favorable at around 100° C. The other oxides require temperatures well over 400° C. for the etching to be feasible. Likely etching reactions for Ta₂O₅ are R1 and R2 in FIG. 16. Of these, reaction R1 is thermodynamically more favorable.

In an embodiment, oxide films Ta₂O₅, TiO₂, ZrO₂, HfO₂, and Al₂O₃ studied in the etching experiments may be prepared by atomic layer deposition in an F-120 flow-type ALD reactor at approximately 1-10 mbar pressure with N₂ (99.999%) used as the carrier/purge gas. The deposition parameters of these films are presented in Table 1. H₂O from an external source at room temperature was used as the oxygen precursor in all cases. Metal precursors were held inside the reactor in heated glass boats, except for trimethylaluminum and TiCl₄, which were held in external sources at room temperature.

In an embodiment, Ta₂O₅, Al₂O₃, SiO₂ and TiO₂ films were etched by gas phase pulsed etching (GPPE) in an F-120 reactor. NbCl₅, held inside the reactor in a glass boat at 80° C., was pulsed for a given time onto the surface, followed by a purge with N₂. These etch/purge cycles were repeated for a number of times to achieve the desired etch depth. The film thicknesses were measured before and after the etching experiments with a four wavelength ellipsometer to observe the thickness etched.

In an embodiment, Ta₂O₅ etching was taken as the model material for etching with NbCl₅. Etching of Ta₂O₅ was particularly studied at the temperature range of 275-400° C.

The pulsing parameters of the etchant were studied first. The NbCl₅ pulse and purge times were varied while the other parameters were kept constant. FIG. 2 shows that the EPC grows linearly with the NbCl₅ pulse length when the purge period is 3 s, which indicates a constant etch reaction. The purge time is seen to affect the EPC as well, increasing with longer purge times up to 3 s. The increase is attributed to better evacuation of the etch products and better saturation of NbCl₅ vapor over the source boat during the extended purge.

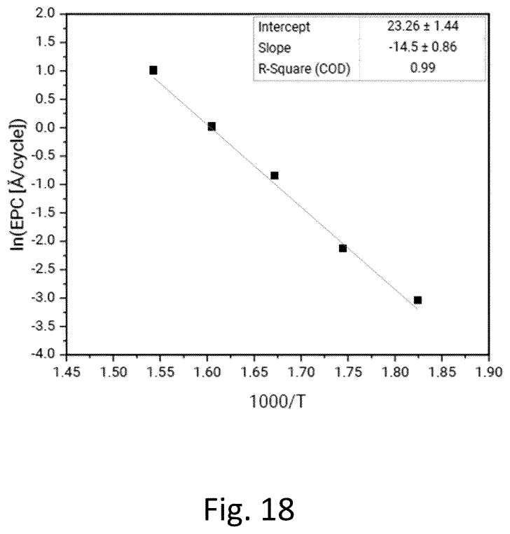

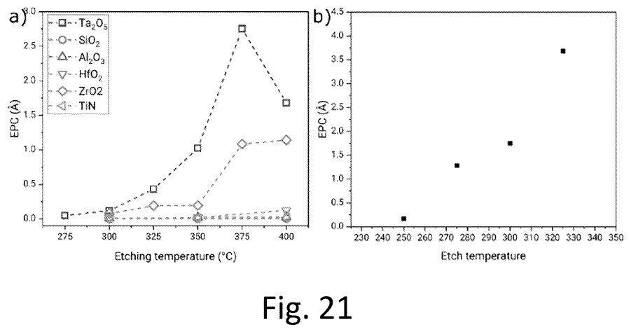

The effect of the etch temperature was studied and it was found that the EPC increases up to 375° C., but declines at 400° C. (FIG. 21). The EPC at 275-375° C. follows an Arrhenius dependence on temperature (FIG. 18) and from the slope a reaction activation energy of 120 KJ/mol is approximated.

The etch products were studied in a modified F-120 reactor equipped with a quadrupole mass spectrometer. The mass spectrum of NbCl₅ was measured prior to the experiment and various peaks corresponding to HCl, NbOCH₃ and NbCl₅ fragments were detected. The HCl and NbOCl₃ are presumed to originate from reaction of the etchant with residual water in the reactor.

In an embodiment, Ta₂O₅ was grown in situ and etched with NbCl₅. The peaks observed during the etchant pulses in this experiment corresponded to the previously detected etchant fragments, as well as fragments of TaCl₅.

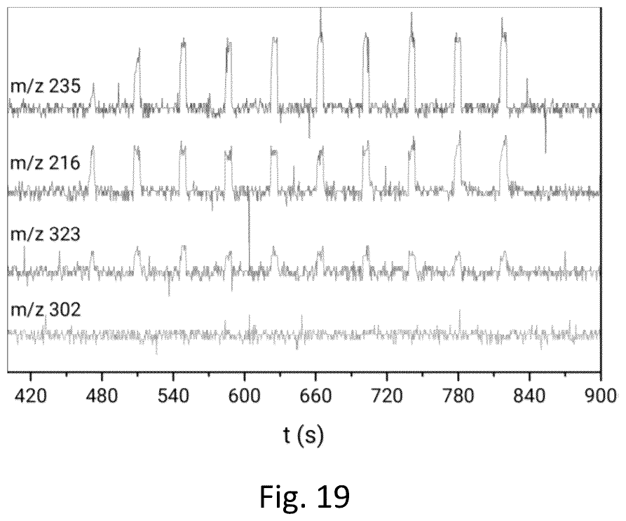

Values for m/z 235 and 216, which correspond to [NbCl₄]+ and [NbOCl₃]+, as well as m/z 323 and 302, which correspond to [TaCl₄]+ and [TaOCl₃]+, were monitored during etchant pulsing (FIG. 19). It is evident that the main etch product is TaCl₅, corresponding to the thermodynamic prediction of the etch reaction: Ta₂O₅+5 NbCl₅ (g)→2 TaCl₅ (g)+5 NbOCl₃ (g).

Residues on the partially etched films were studied using energy-dispersive X-ray spectroscopy (EDS) and x-ray photoelectron spectroscopy (XPS). Ex situ measurements of the films showed only Ta, O, and C on the films surface. Without the subject matter of the present disclosure being limited by any particular theory or mode of operation, it is believed that carbon is most likely from atmospheric contamination. After complete etching of the film, only Si, O, and C were seen on the surface. In situ XPS measurement after the etchant pulse showed a minor contamination of Cl on the film surface. As the ex situ measurements did not detect Cl, it is likely that this contamination is advantageously hydrolyzed in air, and as such, limited to the film surface.

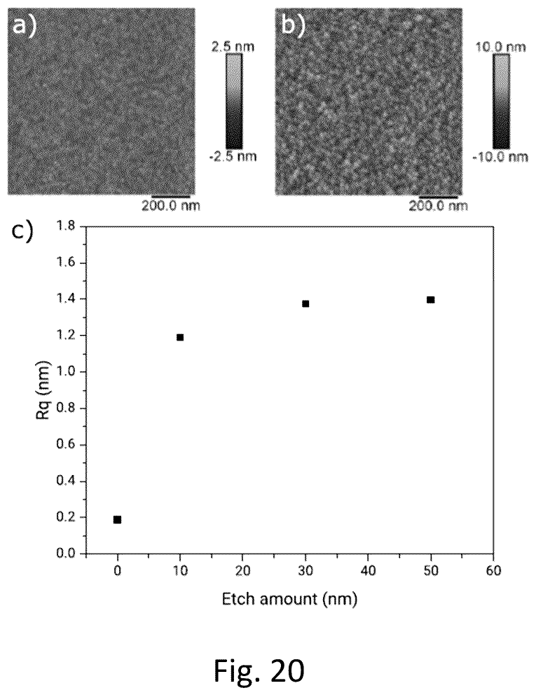

A series of films etched employing a method according to an embodiment of the present disclosure to different depths were analyzed using atomic force microscopy (AFM) (FIG. 20). Some roughening of the films is evident, but it is seen that the roughness does not increase beyond 1.4 nm Rq. As the films are amorphous, the cause of this roughening is likely stochastic effects in etching. Another possibility is that there are some etch-resistant crystalline domains in the films small enough that they are not detected in XRD, or that the surface reactions are causing some sort of recrystallization. The XRD measurements after etching were similar to those before, indicating no crystallization during the process.

Etching of TiO₂ was tested at 250-350° C. and etching of ZrO₂, HfO₂, SiO₂, and TiN at 300-400° C. Etch per cycle (EPC) values in Å are represented in FIG. 6a. Consistent EPC values for the TiO₂ etching cannot be given as the etching was hard to control on this material and minor imperfections in the films caused variable etch rates across the film surface. The film surfaces were also altered/changed to some degree such that consistent modeling of the ellipsometer results proved very difficult. Approximate EPC values for etching TiO₂ films grown with TiCl₄ and H₂O are presented in FIG. 6b.

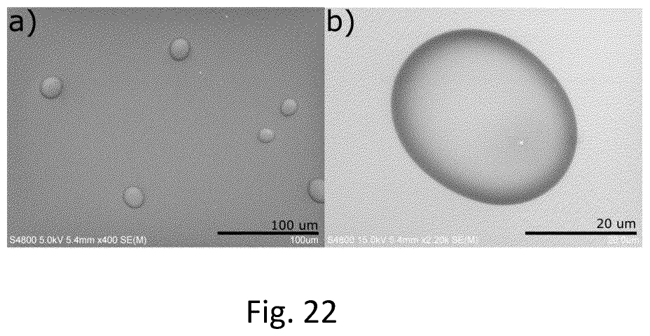

As can be seen in FIG. 21, Ta₂O₅ and ZrO₂ can be etched selectively over SiO₂, Al₂O₃, HfO₂, and TiN. Some minor pitting of the Al₂O₃ films was observed with SEM (FIG. 22), but according to EDS these features do not go through the film. The cause of these features is currently unknown. Some Nb was also detected with XPS on the Al₂O₃ film surfaces after the etching experiment, but this was a minor amount and couldn't be detected with the less surface sensitive EDS. It shall be noted that the selectivity between ZrO₂ and HfO₂ is unexpected as the thermodynamics of etching for these two materials are very similar. Previous literature shows that in thermal atomic layer etching the crystallinities of HfO₂ and ZrO₂ can significantly affect their EPC values, but in this case both of these materials were crystalline according to XRD measurements.

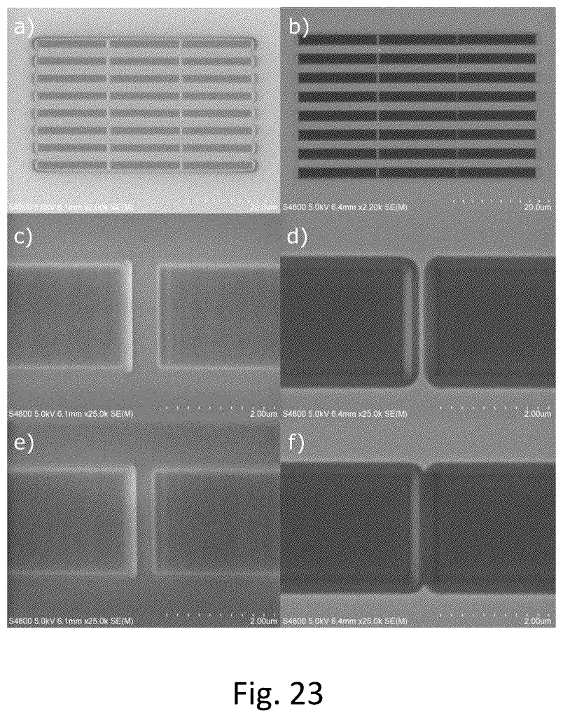

Applicability of selective etching according to an embodiment of a method of the present disclosure was further studied with a pattern etch test. A 50 nm thick Al₂O₃ film was deposited on top of a 40 nm thick Ta₂O₅ layer and removed in a trench pattern with a Ga₊ focused ion beam. This patterned double layer was etched with 2500 cycles of NbCl₅ at 350° C. SEM images of the patterned film before and after etching are presented in FIG. 23. The etched pattern shows the contrast between the remaining double layer and the Al₂O₃ layer undercut by the etching. The isotropic nature of this etching process is also evident from the undercut, especially at the rounded corners of the pattern.

In an embodiment of a method according to the present disclosure, tantalum metal was etched employing NbCl₅ as a volatilization reactant and O₂ as a conversion reactant. In particular, tantalum metal thin films were etched. Tantalum, renowned for its exceptional corrosion resistance, holds significant importance across various industries, including microelectronics, catalysis, and energy storage. In this embodiment, 40 nm thick Ta films were deposited via filtered cathodic arc discharge (FCAD) and subsequently subjected to an etching method according to an embodiment of the present disclosure, particularly employing a substrate temperature of 300° C. Stoichiometry of the films was studied by X-ray photoelectron spectroscopy (XPS) at each step of the etch process. Notably, it was found that NbCl₅ effectively removes the tantalum oxide layers starting from the highest oxidation states until the lower ones resulting in the stoichiometry reminiscent of the surface after sputtering.

Thus, in some embodiments, certain metal halides such as NbCl₅ can be employed as an etchant for selective etching of some oxides such as Ta₂O₅, TiO₂ and ZrO₂ over other oxides and nitrides such as HfO₂, SiO₂, Al₂O₃, and TiN. No significant metal residues were detected on the etched films after the process.

1. A method of etching, comprising:
providing a substrate to a reaction chamber, the substrate comprising an etchable layer, the etchable layer comprising a metal;
executing a cyclical etching process comprising a plurality of etching cycles,
at least one of the plurality of etching cycles comprising a conversion reactant pulse that comprises exposing the substrate to a conversion reactant; and
at least one of the plurality of etching cycles comprising a volatilization reactant pulse that comprises exposing the substrate to a volatilization reactant;
thereby etching the etchable layer;
wherein the volatilization reactant comprises a metal halide.

2. The method according to claim 1, wherein the substrate further comprises a second layer, and wherein the second layer is not substantially etched during the cyclical etching process, thus selectively etching the etchable layer versus the second layer.

3. The method according to claim 1, wherein the cyclical etching process is carried out thermally.

4. The method according to claim 1, wherein the conversion reactant comprises an oxygen reactant.

5. The method according to claim 4, wherein the oxygen reactant comprises O₂.

6. The method according to claim 1, wherein the volatilization reactant pulse is followed by a first purge.

7. The method according to claim 6, wherein the conversion reactant pulse is followed by a second purge.

8. The method according to claim 1, wherein at least one of plurality of etching cycles comprises both a conversion reactant pulse that comprises exposing the substrate to a conversion reactant and a volatilization reactant pulse that comprises exposing the substrate to a volatilization reactant.

9. A method of selectively etching, comprising
providing a substrate to a reaction chamber, the substrate comprising an etchable layer, the etchable layer comprising a metal, the substrate further comprising a second layer;
executing a cyclical etching process that comprises alternatingly exposing the substrate to a vaporization reactant and a purge gas;
thereby etching the etchable layer;
wherein the volatilization reactant comprises a metal halide; and,
wherein the second layer is not substantially etched during the cyclical etching process.

10. The method according to claim 9, wherein the volatilization reactant comprises a transition metal halide.

11. The method according to claim 10, wherein the volatilization reactant comprises a transition metal chloride.

12. The method according to claim 10, wherein the volatilization reactant comprises niobium pentachloride (NbCl₅).

13. The method according to claim 10, wherein the volatilization reactant comprises vanadium pentachloride (VCl₅).

14. The method according to claim 9, wherein the etchable layer comprises at least 90 atomic percent of the metal.

15. The method according to claim 9, wherein the metal comprises a transition metal.

16. The method according to claim 15, wherein the transition metal comprises at least one of tantalum or molybdenum.

17. The method according to claim 9, wherein the etchable layer comprises at least one of Ta₂O₅, TiO₂ or ZrO₂.

18. The method according to claim 9, wherein the second layer comprises at least one of HfO₂, SiO₂, Al₂O₃, and TiN.

19. The method according to claim 9, wherein the cyclical etching process is carried out at a temperature of at least 250 to at most 450° C.

20. A system comprising a reaction chamber, a substrate support, and a controller, the controller being configured for causing the system to execute a method according to claim 1.
